(19) United States
(12) Patent Application Publication
(10) Pub. No.: US 2020/0123299 A1
(43) Pub. Date: Apr. 23, 2020

(54) PATTERN FORMATION MATERIAL AND PATTERN FORMATION METHOD

(71) Applicant: TOSHIBA MEMORY CORPORATION, Tokyo (JP)

(72) Inventors: Koji ASAKAWA, Kawasaki (JP); Norikatsu SASAO, Kawasaki (JP); Tomoaki SAWABE, Tokyo (JP); Naoko KIHARA, Kawasaki (JP); Shinobu SUGIMURA, Yokohama (JP)

(73) Assignee: TOSHIBA MEMORY CORPORATION, Tokyo (JP)

(21) Appl. No.: 16/718,249

(22) Filed: Dec. 18, 2019

Related U.S. Application Data
(62) Division of application No. 15/703,477, filed on Sep. 13, 2017.

(30) Foreign Application Priority Data
Mar. 17, 2017 (JP) 2017-053469

(51) Int. Cl. C08F 297/02; C08F 212/08; C08F 220/06; C08F 220/18; C09D 153/00; G03F 7/00; C09D 125/14

(52) U.S. Cl. CPC C08F 297/026; C08F 212/08; C08F 220/06; C08F 220/18; C08F 2220/1808; G03F 7/0002; C09D 125/14; C08F 2220/1825; C09D 153/00

(57) ABSTRACT

According to one embodiment, a pattern formation material is included in a polymer layer to be provided between a block copolymer layer and a substrate. The block copolymer layer includes a block copolymer including a plurality of blocks. The pattern formation material includes a pattern formation polymer. The pattern formation polymer consists of a main chain including an acrylic backbone, and a side chain. One of the plurality of blocks include a plurality of polymer components. The plurality of polymer components are of mutually-different types. A solubility parameter of the pattern formation material is between a maximum value and a minimum value of a solubility parameter of the polymer components.

### CROSS-REFERENCE TO RELATED APPLICATIONS

This application is based upon and claims the benefit of priority from Japanese Patent Application No. 2017-053469, filed on Mar. 17, 2017; the entire contents of which are incorporated herein by reference.

### FIELD

Embodiments described herein relate generally to pattern formation material and pattern formation method.

### BACKGROUND

Patterning using a pattern formation material is performed to manufacture a semiconductor device. A pattern formation material that makes it easier to perform the patterning is desirable.

### BRIEF DESCRIPTION OF THE DRAWINGS

FIG. 1 is a view showing a phase separation obtained when homopolymer or a random copolymer are used for a block copolymer layer; and

FIG. 2A to FIG. 2E are vies showing a pattern formation method according to an embodiment.

### DETAILED DESCRIPTION

According to one embodiment, a pattern formation material is included in a polymer layer to be provided between a block copolymer layer and a substrate. The block copolymer layer includes a block copolymer consisting of a plurality of blocks. The pattern formation material includes a pattern formation polymer. The pattern formation polymer consists of a main chain including an acrylic backbone, and a side chain. One of the plurality of blocks include a plurality of polymer components. The plurality of polymer components are of mutually-different types. A solubility parameter of the pattern formation material is between a maximum value and a minimum value of a solubility parameter of the polymer components.

According to one embodiment, a pattern formation method includes providing a resist layer on a substrate. The resist layer has an opening. The method further includes providing a polymer layer including a pattern formation material on the resist layer. The method further includes forming a block copolymer layer in the opening of the resist layer. The block copolymer layer includes a plurality of blocks. One of the blocks includes a plurality of polymer components. The polymer components are of mutually-different types. A solubility parameter of the pattern formation material is between a maximum value and a minimum value of a solubility parameter of the polymer components. The method further includes forming a first domain and a second domain by causing micro-phase separation of the block copolymer layer. An etching resistance of the second domain is weaker than an etching resistance of the first domain. The method further includes etching the second domain, the polymer layer, and the substrate.

Embodiments of the invention will now be described with reference to the drawings. Components that are marked with the same reference numeral correspond to each other. The drawings are schematic or conceptual; and the relationships between the thicknesses and widths of portions, the ratios of the sizes between the portions, etc., are not necessarily the same as the actual values thereof. There are also cases where the dimensions and/or the ratios are illustrated differently between the drawings, even in the case where the same portion is illustrated.

### First Embodiment

Technology that utilizes a BCP (Block-Co-Polymer) in which multiple types of polymer blocks are linked is being investigated to allow downscaling of the patterning. Micro phase separation of the BCP is performed; the BCP is aligned to have the desired position and direction; and a substrate can be patterned using the BCP as a template (a mask).

Among the BCP micro phase separation forms, a method that utilizes a lamella or cylinder phase-separated structure is being devised as a method for making a line-and-space (L/S) pattern which is one typical pattern in a semiconductor device.

A L/S pattern is formed of the BCP lamella structure. Or, a hole pattern is formed using the BCP cylinder structure. In such cases, a polymer layer that has high affinity with the compositions of each of the polymer components included in the block copolymer is formed on a substrate.

In DSA (Directed Self-Assembly), the pattern formation material is provided at the lower layer of the BCP so that the BCP microdomains stand vertically. Generally, a random copolymer that includes the same type of polymer as the polymer components included in the BCP is used as the pattern formation material of the lower layer.

For example, there are cases where the BCP is a diblock copolymer consisting of two types of polymers (polymer components). In such a case, generally, a random copolymer that includes the two components included in the diblock copolymer is used as the pattern formation material to neutralize the surface to the block copolymer. For example, in the case where the BCP is PS (polystyrene)-b-PMMA (poly methyl methacrylate), the random copolymer (PS-r-PMMA) that is used as the pattern formation material includes PS and PMMA which are the same two types of polymers as the polymers included in the BCP.

On the other hand, in DSA patterning, the difference between the reactive ion etching (RIE) resistances and the like of the block copolymer is utilized. In the case where the same material as the BCP is used as the pattern formation material, the RIE resistance of the pattern formation material is undesirably between those of the multiple polymers included in the block copolymer. Therefore, there are cases where portions remain that should be removed more quickly during the RIE. This is caused by the RIE resistance of the pattern formation material not being low enough. Pattern defects are caused when the portions that should be removed remain.

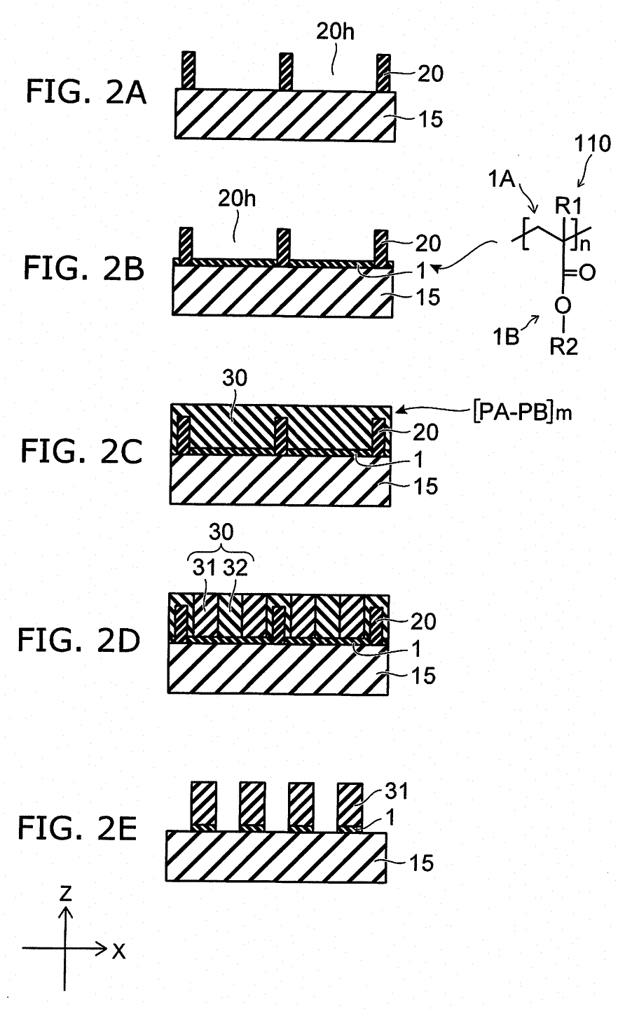

In the embodiment, the block copolymer includes multiple blocks. One of the multiple blocks includes multiple polymer components (e.g., PS, PMMA, etc.). The types of the multiple polymer components are different from each other. A polymer layer is provided between the substrate and the block copolymer. The polymer layer includes the pattern formation material according to the embodiment. The pattern formation material includes a pattern formation polymer 110 shown in FIG. 2B. The pattern formation polymer 110 consists of a main chain (a main chain 1A referring to FIG. 2B). In FIG. 2B, “R1” represents hydrogen or methyl group. “R2” represents an alkyl group whose carbon number is not less than 1 and not more than 10. The main chain has an acrylic backbone. In the first embodiment, a homopolymer is used as the polymer having the acrylic backbone in the main chain. The solubility parameter of the polymer having the acrylic backbone in the main chain is between the maximum value and the minimum value of the solubility parameters of the multiple types of polymer components (polymers) included in the BCP.

For example, two polymers (a first polymer and a second polymer) are included in the BCP. The solubility parameter δ of the first polymer is taken as δA. The solubility parameter δ of the second polymer is taken as δB. The solubility parameter δ of a polymer layer U provided at the lower layer of the BCP is taken as δU. In such a case, the repulsive force per unit volume (in this case, per segment) acting between the polymer layer U and the first polymer of the BCP is proportional to (δA−δU)². A similar relationship exists between the second polymer and the polymer layer U as well. Therefore, it is considered that the vertically aligned state is stable as a view point of free energy when the δU of the polymer layer U happens to be an intermediate value between the solubility parameter δA of the first polymer and the solubility parameter SB of the second polymer. In an actual polymer, it is uncommon when the δU happens to be an intermediate value. The vertical alignment of the DδA is stable when the solubility parameter δU is between δA and δB. As a result, the BCP microdomain of the DδA can stand vertically. In the case where such a material is used, it is unnecessary to use a material (e.g., a polymer to which a phenyl group is linked, etc.) having a high RIE resistance to the etching, etc. It is possible to quickly remove the lower layer by RIE.

The results of calculating the solubility parameters of polymers having an acrylic backbone at the main chain are shown in Table 1.

TABLE 1

| | Polymer Solubility | | | |
|---|---|---|---|---|
| | Parameter | Polymer Molar | Molecular | Polymer Tg |
| Chemical Sample | ((J/cc)^{0.5}) | Volume (cc/mole) | Weight | (Kelvin) |
| poly methyl methacrylate | 17.675 | 86.415 | 102.133 | 355.471 |
| poly ethyl methacrylate | 17.160 | 104.394 | 116.160 | 328.809 |
| poly n-propyl methacrylate | 17.112 | 120.474 | 130.186 | 310.058 |
| poly iso-propyl methacrylate | 16.626 | 121.612 | 130.186 | 342.523 |
| poly n-butyl metacrylate | 17.075 | 136.554 | 144.213 | 295.067 |
| poly iso-butyl metacrylate | 16.691 | 138.192 | 144.213 | 324.584 |
| poly t-butyl metacrylate | 16.141 | 138.337 | 144.213 | 353.172 |
| poly n-pentyl metacrylate | 17.046 | 152.634 | 158.240 | 282.807 |
| poly n-hexyl metacrylate | 17.022 | 168.714 | 172.267 | 272.594 |
| poly cyclohexyl metacrylate | 17.058 | 153.341 | 170.251 | 391.598 |
| poly trifluoroethyl methacrylate | 16.151 | 114.547 | 170.131 | 335.369 |
| poly glycidyl methacrylate | 17.982 | 112.019 | 144.170 | 357.200 |

The molecular weight in Table 1 shows the molecular weight of the polymer. The polymer Tg shows the glass transition temperature (K (Kelvin)) of the polymer.

As the method of the calculation, the structure of an acrylic monomer is optimized using the molecular orbital method MOPAC. In the model of the calculation, the main chain of the polymer is a single bond of C—C; and the two terminals of the C—C bond are linked to the next segments. By using this model, the solubility parameter and the glass transition temperature were calculated. The method described in J. Bicerana, “Prediction of Polymer Properties,” Marcel Dekker (1996) was used. In this method, the solubility parameter or the glass transition temperature due to the difference of the side chains can be predicted systematically if the polymer (e.g., the polymer having the acrylic backbone in the main chain) is of the same system. The main chain is the largest carbon chain in which carbons are linked in a chain configuration. The side chain (a side chain 1B referring to FIG. 2B) is branched from the main chain. The side chain has a chemical structure having a functional group, etc. The state becomes a rubberly state when the glass transition temperature is low, e.g., room temperature or less. If the glass transition point is excessively low, there are cases where the BCP provided at the upper portion of the polymer layer including the pattern formation material according to the embodiment is unstable. Therefore, it is favorable for the glass transition temperature to be high.

For example, among the materials illustrated in Table 1, poly methyl methacrylate is suitable as the polymer layer when the maximum value of the solubility parameter of the BCP is 17.8 and the minimum value is 17.5.

From the results of Table 1, it can be seen that the solubility parameter is relatively low for the polymers in which the alkyl group of the side chain is long and the main chain has an acrylic backbone. For example, in Table 1, comparing the solubility parameter of only the normal forms: the solubility parameter of poly methyl methacrylate is 17.675; the solubility parameter of poly ethyl methacrylate is 17.160; the solubility parameter of poly n-propyl methacrylate is 17.112; the solubility parameter of poly n-butyl metacrylate is 17.075; the solubility parameter of poly n-pentyl metacrylate is 17.046; and the solubility parameter of poly n-hexyl metacrylate is 17.022. The solubility parameter decreases as the side chain lengthens. For example, in the case where a value between the maximum value and the minimum value of the solubility parameters of the multiple polymers included in the BCP is lower than the solubility parameter of the polymer having the acrylic backbone in the main chain, it is favorable for the alkyl group of the side chain to be long. In the case where the alkyl group of the side chain is long, there is a tendency for the glass transition temperature to be low. In the case where the side chain is too long, the RIE resistance that is predicted from the Ohnishi parameter which is an indicator of the RIE resistance is excessively high. The Ohnishi parameter illustrates the carbon density per polymerizable unit volume. Generally, the RIE resistance improves as the Ohnishi parameter decreases (non-patent document: H. Gokan, S. Eshoand, Y. Ohnishi: J. Electrochem. Soc. 130 (1983) 143).

In the polymer having the acrylic backbone in the main chain, it is favorable for the side chain to have an alkyl group in which the number of carbons is 1 to 10. For all of the polymers described in Table 1, the side chain has an alkyl group in which the number of carbons is 1 to 10.

Carboxylic acid is obtained when the number of carbons of the side chain is 0; and the hydrophilic property is way too high. In the case where the number of carbons of the side chain is greater than 10, the RIE resistance is too high.

From Table 1, iso-propyl-methacrylate (fourth from the top of Table 1) and n-propyl-methacrylate (third from the top of Table 1) which are acrylics having a side chain in which the number of carbons is 3 will now be compared. It can be seen that the glass transition temperature of the iso form is higher than the glass transition temperature of the normal form. From this result, it is considered that an alkane having a branch is good for the side chain of the acrylic. This tendency is similar also for butylmethacrylate in which the number of carbons is 4. In other words, this shows that it is favorable for the alkyl group to have a branch.

It was found that there are cases where defects occur in the pattern after annealing the BCP at a high temperature. The defects are isotropic defects. It was found that the defects were not defects caused by impurities inside the resist, etc., or unevenness when coating. As a result of investigations, it was found that the defects after the annealing occur as a result of a portion of the pattern formation material becoming an acid due to thermal decomposition, and the acid diffusing isotropically into the periphery due to an autocatalytic reaction. This is because the heat resistance is low for the side chain linked to the acrylic by an ester bond if the link is via tertiary carbon; and thermal decomposition occurs.

### First Example

### Homopolymer Synthesis

TABLE 2

| | | | | | poly | | |
|---|---|---|---|---|---|---|---|
| | | poly methyl | poly isopropyl | poly t-butyl | trifluoroethyl | | |
| | | methacrylate | methacrylate | methacrylate | methacrylate | PS | PS-r-PMMA |
| | | 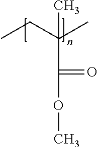 | 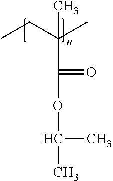 | 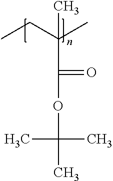 | 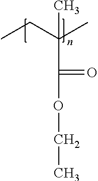 | 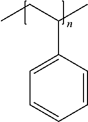 | 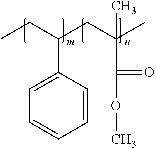 |
| Calculated solubility | | 17.675 | 16.626 | 16.141 | 16.151 | | |
| parameter | | | | | | | |
| Contact | polymer | 65.2 | 76.0 | 89.3 | 93.9 | 86.4 | 75.3 |
| Angle | After | 63.6 | 77.2 | 85.7 | 95.0 | 89.3 | 75.5 |
| | rinsed by | | | | | | |
| | PGMEA | | | | | | |

The multiple types of monomers shown in Table 2 are placed respectively in round-bottom flasks. The amount of each of the multiple monomers is 0.05 mol. 0.001 mol of glycidylmethacrylate was added as an adhesive for a substrate 15 shown in FIG. 2A; and 0.0005 mol of azobisisobutyronitrile (AIBN) was added as a polymerization initiator. Tetrahydrofuran of five times the monomer weight is used as a polymerization solvent. Polymerization was performed for 8 hours at a polymerization temperature of 60° C. After 8 hours, the reaction was stopped by adding several drops of methanol to the reaction solution. Subsequently, reprecipitation was performed inside a 4:1 (weight ratio) mixed liquid of methanol and water. The polymer that was obtained by the reprecipitation was dried in air for about one week. As a result, a polymer having a yield of about 55% was obtained. The molecular structure was confirmed using nuclear magnetic resonance (NMR). The molecular weight was confirmed using gel permeation chromatography (GPC). The glycidylmethacrylate corresponds to 2 mol % inside the polymer. The glycidylmethacrylate substantially does not affect the properties of the polymer. In the description recited above, a radical polymerization is performed. In the embodiment, the synthesis may be performed using reversible addition-fragmentation chain transfer (RAFT) polymerization, etc. In such a case, a hydroxy group may be used as an adhesive group for the substrate 15. The properties of the polymer obtained using this method are the same as the properties of the polymer obtained by radical polymerization.

### Process

The polymer that is synthesized is dissolved in 1-methoxy-2-propylacetate (PGMEA); and a solution of 2 wt % is obtained. After performing UV processing of the substrate 15 (e.g., a silicon substrate), the solution was spin-coated onto the substrate 15. Thereby, a polymer layer 1 having a thickness of about 100 nm was formed on the substrate 15. The polymer layer 1 and the substrate 15 were chemically bonded and fixed by performing annealing. The contact angle with water was measured for the obtained film (the polymer layer 1). As a result, the sequence in order of size of the measured values of the contact angles of the multiple polymer layers 1 obtained from the multiple types of monomers was the same as the sequence in order of size of the calculated values obtained from the molecular orbital calculation; and the calculations and the experimental results matched.

The upper layer portion of the polymer layer 1 obtained as recited above was removed by rinsing the polymer layer 1 three times with PGMEA. The contact angle of the substrate 15 surface does not change even if the polymer is peeled by the PGMEA. Therefore, it is considered that one layer (having a thickness not less than 1 nm but less than 10 nm) of a film of a portion of the polymer layer 1 is chemisorbed on the substrate 15 and remains. The synthesized polymer includes 2 mol % of a glycidyl group (the source material of an epoxy adhesive). It is considered that this portion is adsorbed to the substrate 15. In the synthesized polymer, the contact angle of Poly-isoPropyl Methacrylate (PisoProMA) is near the contact angle of the pattern formation material (the random copolymer consisting of PS and PMMA) in which the PS-b-PMMA can have the vertical alignment.

A direction perpendicular to a major surface of the substrate 15 is taken as a Z-axis direction. One direction perpendicular to the Z-axis direction is taken as an X-axis direction. A direction perpendicular to the Z-axis direction and the X-axis direction is taken as a Y-axis direction.

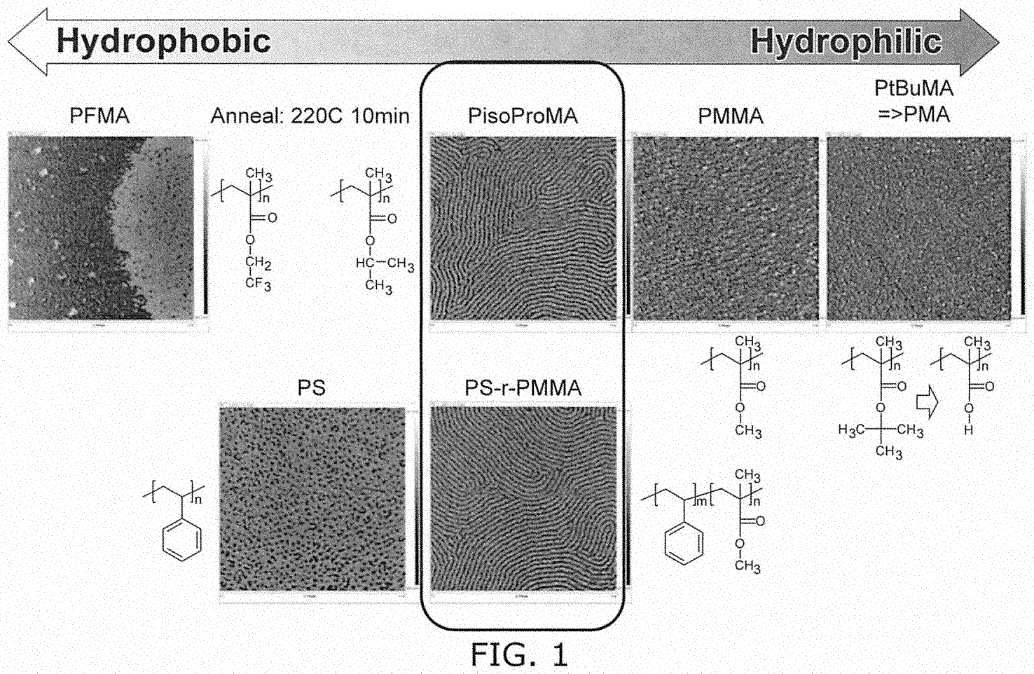

PS-b-PMMA was coated onto the remaining polymer layer on the substrate 15. Annealing was performed on a hotplate for 10 minutes at 220° C. As shown in FIG. 1, a fingerprint-like micro phase separation pattern can be observed for the PS-b-PMMA coated onto the PisoProMA and the PS-b-PMMA coated onto the PS-r-PMMA; and vertical alignments were confirmed. Thereby, the function as the pattern formation material was confirmed. The vertical alignment was not confirmed for the other polymers. It is considered that the hydrophilic and hydrophobic characteristics do not match between PS-b-PMMA and the other polymers.

Thus, it is shown that it is possible to design the pattern formation material using parameters that are predicted theoretically. The parameters that are necessary for the polymer are mutually-independent parameters such as the hydrophilic/hydrophobic properties, the RIE resistance, the mechanical strength, the metallization ease, etc. Therefore, it is possible to design polymers corresponding to the application.

The results of measuring the RIE resistance of the pattern formation materials that were designed will now be described using Table 3.

TABLE 3
RIE rate (nm/s)

| | |
|---|---|
| PS | 0.14 |
| PMMA | 0.44 |
| PS-r-PMMA | 0.30 |
| PisoProMA | 0.42 |
| PtBuMA | 0.60 |
| PTFEMA | 0.53 |

The pattern formation material was spin-coated onto the substrate 15; and the resistance to RIE was measured. Oxygen was included in the RIE gas. Oxygen RIE generally is used in the patterning of BCPs. In the RIE, the flow rate of the oxygen gas was 5 sccm; the input was 50 W; and the bias was 5 W. The change of the thickness of the sample before and after the RIE was measured using an AFM; and the RIE rate was estimated from the difference.

From the results of Table 3, it can be seen that the RIE resistance of the polymer having the acrylic backbone in the main chain is equal to or lower than the RIE resistance of PMMA. Thereby, it is easy to vertically remove the pattern formation material positioned under the PMMA in the RIE. An improvement of the pattern configuration is realized.

A pattern formation method using the pattern formation material according to the embodiment will now be described using FIG. 2A to FIG. 2E.

FIG. 2A to FIG. 2E are drawings showing the pattern formation method according to the example.

The polymer layer 1 that includes the pattern formation material according to the embodiment recited above is used. The polymer layer 1 is provided on the substrate 15. The substrate 15 is, for example, a Si substrate.

First, in the pattern formation method according to the embodiment as shown in FIG. 2A, a process of forming a guide layer 20 having an opening 20h is performed first using photolithography or nanoimprint lithography. After forming the guide layer 20, the guide layer 20 is made insoluble to the solvent that dissolves the BCP.

Then, as shown in FIG. 2B, the polymer layer 1 is coated onto the guide layer 20. The polymer layer 1 is provided on the substrate 15 in the opening 20h.

Generally, much of the guide layer 20 is adsorbed to the bottom portion of the guide. In FIG. 2B, the height of the guide layer 20 is drawn as being higher than the height of the polymer layer 1. The state of graphoepitaxy is drawn. In the embodiment, the height of the guide layer 20 may be substantially equal to the height of the polymer layer 1. Chemoepitaxy may be used. The solubility parameter of the polymer layer 1 is between the maximum value and the minimum value of the solubility parameters of the multiple polymer components included in the BCP used in the processes described below.

As shown in FIG. 2C, a process of forming a BCP layer 30 inside the opening 20h is performed. The BCP layer 30 includes the BCP.

The BCP layer 30 is formed by dissolving the BCP consisting of the two types of polymers (the first polymer and the second polymer) and by pouring the BCP into the opening 20h. The solvent that dissolves the BCP includes, for example, an aromatic hydrocarbon such as toluene, xylene, mesitylene, etc. The solvent may include, for example, cyclohexanone. The solvent may include a ketone such as acetone, ethyl methyl ketone, methyl isobutyl ketone, etc. The solvent may include a cellosolve such as methyl cellosolve, methyl cellosolve acetate, ethyl cellosolve acetate, butyl cellosolve acetate, propylene glycol monomethyl ether acetate (PGMEA), etc. The solvent may include a combination of two or more types of materials.

Then, as shown in FIG. 2D, a process of forming, inside the opening 20h, a first domain 31 including much of the second polymer and a second domain 32 including much of the first polymer is performed by causing micro phase separation of the BCP layer 30 by annealing. In the following example, the BCP includes two types of polymers (the first polymer and the second polymer); and the surface energy of the second polymer is smaller than the surface energy of the second polymer.

The affinity between the first polymer and the guide layer 20 is high in the case where the absolute value of the difference between the surface energy of the guide layer 20 and the surface energy of the second polymer is less than the absolute value of the difference between the surface energy of the guide layer 20 and the surface energy of the first polymer. In such a case, the first polymer concentrates easily at the side wall of the guide layer 20. On the other hand, the affinity between the second polymer and the guide layer 20 is high in the case where the absolute value of the difference between the surface energy of the guide layer 20 and the surface energy of the first polymer is less than the absolute value of the difference between the surface energy of the guide layer 20 and the surface energy of the second polymer. In such a case, the second polymer concentrates easily at the side wall of the guide layer 20.

The first domain 31 and the second domain 32 are formed by performing micro phase separation of the BCP layer 30 by annealing. In the example, a pattern having a vertical lamella structure is formed. The lamella structure includes the first domain 31 and the second domain 32. In the embodiment, the annealing method and the annealing atmosphere of the BCP are not particularly limited.

For example, the micro phase separation of the BCP may be performed by annealing in air. For example, the micro phase separation may be performed by heating (annealing) inside a forming gas including an inert gas and a gas having a reduction effect such as hydrogen, etc. The atmosphere of the annealing may be at reduced pressure (in a vacuum). The atmosphere of the annealing may be an inert gas such as argon, nitrogen, etc. An oven, a hotplate, or the like is used favorably as the annealing apparatus. The annealing may be performed using a method other than heating. For example, a method (a solvent annealing method) of exposing the BCP to a solvent atmosphere may be used as the micro phase separation method.

The solvent that is used in the solvent annealing includes, for example, an aromatic hydrocarbon such as toluene, xylene, mesitylene, etc. The solvent that is used in the solvent annealing may include a ketone such as cyclohexanone, acetone, ethyl methyl ketone, methyl isobutyl ketone, etc. The solvent that is used in the solvent annealing may include a cellosolve such as methyl cellosolve, methyl cellosolve acetate, ethyl cellosolve acetate, butyl cellosolve acetate, etc. The solvent that is used in the solvent annealing may be a good solvent such as tetrahydrofuran, chloroform, etc. The solvent that is used in the solvent annealing may include a combination including two or more types of materials. In the case where the affinity between the guide layer 20 and one of the polymers included in the BCP layer 30 is higher than the affinity between the guide layer 20 and another polymer of the polymers included in the BCP layer 30, the one polymer of the polymers included in the BCP recited above concentrates easily at the side wall of the guide layer 20. The affinity of the first domain 31 for the guide layer 20 is higher than the affinity of the second domain 32 for the guide layer 20.

Then, as shown in FIG. 2E, a process of removing the guide layer 20, the second domain 32, and the polymer layer 1 is performed.

For example, RIE is used to remove the second domain 32 and the polymer layer 1 and cause the first domain 31 to remain. The RIE is performed to reach the substrate 15. It is desirable for the RIE resistance of the second domain 32 to be lower than the RIE resistance of the first domain 31. The guide layer 20 also is etched simultaneously in the case where the etching resistance of the guide layer 20 is low.

In the case where the RIE resistance of the polymer layer 1 is high, the pattern formation may become difficult. It is favorable for the RIE resistance of the polymer layer 1 to be low. Or, a process of deposition of a metal material, etc. (not illustrated) is performed.

In the process of the pattern formation, there are cases where defects occur in the pattern after annealing the BCP at a high temperature. These defects of the pattern are isotropic defects. It is considered that these defects of the pattern are not defects caused by impurities inside the resist, etc., or unevenness when coating. A portion of the pattern formation material thermally decomposes and becomes an acid. It was found that the defects of the pattern occur when the acid is diffused isotropically into the periphery by the autocatalytic reaction.

The polymer having the main chain of the acrylic backbone decomposes at about 150° C. in the case where the carbon directly added to the carboxyl group is tertiary carbon. In the case where the carbon directly added to the carboxyl group is secondary carbon, the decomposition is suppressed even if 200° C. is exceeded. However, in the case where the pattern formation material is used as the polymer layer 1, it is considered that the pattern formation material becomes hydrophilic due to a small amount of acrylic that decomposes autocatalytically. Thereby, it is considered that the structure of the pattern of the BCP changes. As a result, it was found that the defects of the pattern occur.

It was found that a structure in which methylene is added to the carboxyl group of the acrylic and an alkyl group having a branch is linked to the end of the methylene is better as a pattern formation material that can also withstand high-temperature annealing. For example, it is favorable for the alkyl group described above to be an iso form.

Thus, it is estimated from the Ohnishi parameter that the RIE resistance is high for the polymer that is designed. By using a polymer thus designed, it is easy to remove the pattern formation material. Due to these characteristics, a low RIE resistance is obtained compared to a conventional method in which a random copolymer including the polymer components included in the BCP is included in the polymer layer 1.

### Second Embodiment

Aspects that are different from the first embodiment will be described.

A pattern formation material according to a second embodiment includes a random copolymer instead of a homopolymer. The random copolymer includes a polymer having an acrylic backbone in the main chain, and a polymer that is different from the polymer having the acrylic backbone in the main chain.

In the homopolymer, the solubility parameter has a determined physical property value. Therefore, the solubility parameter of the homopolymer often is not between the maximum value and the minimum value of the solubility parameters of the multiple polymer components included in the BCP. There are cases where the difference between the maximum value and the minimum value of the solubility parameters is small, and the range of the solubility parameters is narrow. Therefore, the solubility parameter of the pattern formation material is finely adjusted. For a homopolymer, the fine adjustment of the solubility parameter is difficult. On the other hand, in the case where a random copolymer is used, it is possible to change the solubility parameter using the composition ratio of the random copolymer. In the case where the random copolymer is used, it is easy to set the solubility parameter of the pattern formation material to be between the maximum value and the minimum value of the solubility parameters of the multiple polymer components included in the BCP.

### Second Example

### Random Copolymer Synthesis

Multiple types of monomers are mixed according to the composition ratio. Other than using a monomer mixed to have a total of 0.05 mol, the polymerization is performed using a method similar to that of the homopolymer. A first random copolymer is a random copolymer of poly iso-butyl methacrylate (PiBMA) and poly methyl methacrylate (PMMA). A second random copolymer is a random copolymer of poly n-butyl methacrylate (PnBMA) and poly methyl methacrylate (PMMA). A third random copolymer is a random copolymer of poly n-hexyl methacrylate (PnHMA) and poly methyl methacrylate (PMMA). The composition is modified for each of the first to third random copolymers recited above. For the first to third random copolymers, three random copolymers having composition ratios of 20 mol %:80 mol %, 50 mol %:50 mol %, and 80 mol %:20 mol % respectively were synthesized.

The synthesized random copolymers are dissolved in PGMEA; and solutions of 2 wt % are obtained. Random copolymers of composition ratios other than those obtained by the synthesis also can be obtained by mixing the random copolymers obtained by the synthesis. The random copolymers that are obtained by mixing are thermodynamically equivalent to the random copolymers obtained by the synthesis. It is considered that this is because the multiple random copolymers are thermodynamically equivalent if the multiple random copolymers are compatible at the molecular level without phase separation. These are thermodynamically equivalent when using the unit of vol % based on the volume. Here, the unit of mol % is used because the relationship between vol % and mol % is 1:1. For example, a random copolymer of 40 mol %:60 mol % was obtained by mixing a polymer of 20 mol %:80 mol % and a polymer of 50 mol %:50 mol % at the corresponding mol ratio. A process similar to that of the homopolymer was performed for the random copolymer thus obtained. Similarly to the case of the homopolymer, the random copolymer that is obtained is coated onto PS-b-PMMA. The results of the observation of the pattern configuration are shown in Table 4.

TABLE 4

| | | | | | | |
|---|---|---|---|---|---|---|
| 20:80 | 30:70 | 40:60 | 50:50 | 60:40 | 70:30 | 80:20 |

poly iso-propyl methecrylate and poly methyl methacrylate

| | | | | | | |
|---|---|---|---|---|---|---|
| X | X | X | X | X | X | ◯ |

poly iso-butyl methecryIate and poly methyl methacrylate

| | | | | | | |
|---|---|---|---|---|---|---|
| X | ◯ | ◯ | ◯ | X | X | X |

poly n-butyl methacrylate and poly methyl methacrylate

| | | | | | | |
|---|---|---|---|---|---|---|
| X | ◯ | ◯ | X | X | X | X |

poly n-hexyl methecrylate and poly methyl methacrylate

| | | | | | | |
|---|---|---|---|---|---|---|
| ◯ | ◯ | X | X | X | X | X |

In Table 4, “◯” shows where the vertical lamella structure is observed. “x” shows where the vertical lamella structure is not observed.

For PiBMA-r-PMMA, vertical lamellae of PS-b-PMMA were observed in the region where the mol fraction of PiBMA is high. For PnBMA-r-PMMA that has a similar molecular structure as well, the vertical lamellae of PS-b-PMMA were observed in the region having a similar mol fraction. On the other hand, for PnBMA-r-PMMA, partial defects were observed; and it is considered that the margin is narrow. There is a possibility that this is caused by the polymer layer 1 being fluidized because the glass transition temperature of PnBMA is lower than the glass transition temperature of PiBMA. In the case of the random copolymer consisting of poly t-butyl methacrylate (PtBMA), the t-butyl group undesirably decomposes in the annealing for the micro phase separation of the BCP; and the vertical lamellae cannot be obtained. From such results, it can be seen that the iso form is more favorable than the normal form.

In the case where PnHMA-r-PMMA is used as the polymer layer 1, vertical lamellae are obtained in the composition having much PMMA. Defects are observed even in the region where the vertical lamellae are observed. The difference of the solubility parameters is large between PnHMA and PMMA. Therefore, the likelihood is high that the fluctuation of the surface energy inside the polymer layer 1 is large. For PnHMA having a side chain having six carbons, the glass transition temperature is low at the vicinity of room temperature. Therefore, it is possible that the phase-separated structure obtained by the annealing is fluidized. For such a reason, it is considered that it is good for the alkyl chain length of the side chain of the acrylic group not to be excessively long.

In the case where the BCP is a diblock copolymer including two types of polymers, a random copolymer including the two types of polymers included in the diblock copolymer is used as a conventional pattern formation material. For example, in the case where the BCP is PS (polystyrene)-B-PMMA (poly methyl methacrylate), a general pattern formation material is a random copolymer using the same two types of polymers as the BCP (a random copolymer of PS and PMMA (PS-r-PMMA)). Conversely, because the RIE resistance of PS is high, in the case of this method, the PS is not removed easily and causes pattern defects. Conversely, the solubility parameter of the pattern formation material according to the embodiment is between the maximum value and the minimum value of the solubility parameters of the multiple polymer components (e.g., a first polymer component PA and a second polymer component PB referring to FIG. 2C) included in the BCP. The method recited above using the material having the solubility parameter between the maximum value and the minimum value of the solubility parameters is effective also for BCPs having other structures. In particular, a similar phenomenon is obtained by using an acrylic random copolymer if the solubility parameter can be adjusted. For example, in the example described above, a pattern formation material can be provided in which the removal by RIE is easy by replacing the PS having the high RIE resistance with a material having a low RIE resistance.

Although several embodiments of the invention are described, these embodiments are presented as examples and are not intended to limit the scope of the invention. The embodiments may be implemented in other various forms; and various omissions, substitutions, and modifications can be performed without departing from the spirit of the invention. The invention described in the claims and their equivalents is intended to cover such embodiments and their modifications as would fall within the scope and spirit of the description.

1.-7. (canceled)

8. A pattern formation method, comprising:
providing a resist layer on a substrate, the resist layer having an opening;
providing a polymer layer including a pattern formation material on the resist layer, the pattern formation material including a pattern formation polymer;
forming a block copolymer layer in the opening of the resist layer, the block copolymer layer including a plurality of blocks, one of the plurality of blocks including a plurality of polymer components, the plurality of polymer components being of mutually-different types, a solubility parameter of the pattern formation polymer being between a maximum value and a minimum value of a solubility parameter of the plurality of polymer components;
forming a first domain and a second domain by causing micro phase separation of the block copolymer layer, an etching resistance of the second domain being weaker than an etching resistance of the first domain; and
etching the second domain, the polymer layer, and the substrate.

9. The method according to claim 8, wherein the micro phase separation includes annealing.

10. The method according to claim 8, wherein
the pattern formation polymer includes:
a main chain including an acrylic backbone; and
a side chain.

11. The method according to claim 8, wherein the pattern formation polymer includes a homopolymer.

12. The method according to claim 8, wherein the pattern formation polymer includes a random copolymer.

13. The method according to claim 8, wherein
the side chain includes an alkyl group, and
the number of carbons included in the alkyl group is not less than 1 and not more than 10.

14. The method according to claim 13, wherein the side chain includes a branch.

15. The method according to claim 13, wherein the alkyl group is an iso form.

16. The method according to claim 13, wherein the block copolymer includes a diblock copolymer.
